(19) United States
(12) Patent Application Publication
(10) Pub. No.: US 2026/0164627 A1
(43) Pub. Date: Jun. 11, 2026

(54) HEAT DISSIPATION PLATE AND DISPLAY DEVICE USING THE SAME

(71) Applicant: LG Display Co., Ltd., Seoul (KR)

(72) Inventor: SungSik SON, Paju-si (KR)

(73) Assignee: LG Display Co., Ltd., Seoul (KR)

(21) Appl. No.: 19/303,788

(22) Filed: Aug. 19, 2025

(30) Foreign Application Priority Data
Dec. 10, 2024 (KR) 10-2024-0182340

(51) Int. Cl. H05K 7/20

(52) U.S. Cl. CPC H05K 7/20963

(57) ABSTRACT

The present disclosure provides a heat dissipation plate including a base substrate allowing a rear surface of a display panel including a pad portion, a circuit film, and a source PCB that are disposed on a side of the display panel to be disposed on one surface of the base substrate, and a guide holder disposed on the other surface of the base substrate and allowing the circuit film bent from the display panel to be placed, and a display device including the heat dissipation plate.

### CROSS-REFERENCE TO RELATED APPLICATION

This application claims priority from Korean Patent Application No. 10-2024-0182340, filed on Dec. 10, 2024 in the Korean Intellectual Property Office, which is hereby incorporated by reference for all purposes as if fully set forth herein.

### BACKGROUND

### Technical Field

The present disclosure relates to a heat dissipation plate and a display device including the heat dissipation plate.

### Description of the Related Art

In today's information society, display technology for presenting electrical information or data in the form of visual information or images is increasingly important and rapidly developed. As the display technology is advanced, various types of display devices having excellent performance based on lower power consumption and a thinner and lighter package have been developed.

Recently, as such display devices, a liquid crystal display (LCD) device, an organic light emitting display (OLED) device, an inorganic light emitting display (iLED) device, a micro light emitting display (micro LED) device, a mini light emitting displays (mini LED) device, a quantum dot light emitting display (QLED) device, and the like, have been developed.

These display devices can generate a lot of heat while they are driven, and increased temperature due to the generated heat can increases the luminance of a display panel. When the temperature of the display panel increases and the luminance increases, the display panel can suffer from a decrease in the color display uniformity of an image. Further, when a display panel heats up above a certain temperature, the lifetime of the display panel can be reduced.

### BRIEF SUMMARY

To address these issues, one or more aspects of the present disclosure may provide a heat dissipation plate capable of dissipating heat generated in a display panel, and a display device capable of presenting high luminance, having long lifetime, and being driven in low power consumption through the heat dissipation plate.

One or more aspects of the present disclosure may provide a heat dissipation plate that includes a guide holder for placing a circuit film on one surface of the heat dissipation plate and is capable of placing the circuit film and a source PCB connected to the circuit film at an intended location, and a display device including the heat dissipation plate.

One or more aspects of the present disclosure may provide a heat dissipation plate that includes a guide holder for enabling a driver IC to be spaced apart from the heat dissipation plate, and is capable of preventing the driver IC from interfering with the heat dissipation plate, and a display device including the heat dissipation plate.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a heat dissipation plate can be provided that includes a base substrate allowing a rear surface of a display panel including a pad portion, a circuit film, and a source PCB that are disposed on a side of the display panel to be disposed on one surface of the base substrate, and a guide holder disposed on the other surface of the base substrate and allowing the circuit film bent from the display panel to be placed, and a display device including the heat dissipation plate can be provided.

According to one or more example embodiments of the present disclosure, a display device can be provided that includes a display panel including a pad portion, a circuit film, and a source PCB, which are disposed on a side of the display panel, and a heat dissipation plate including a base substrate allowing a rear surface of the display panel to be disposed on one surface of the base substrate, and a guide holder disposed on the other surface of the base substrate and allowing the circuit film bent from the display panel to be placed.

According to one or more aspects of the present disclosure, a heat dissipation plate may be provided that is capable of dissipating heat generated in a display panel, and a display device may be provided that is capable of presenting high luminance, having long lifetime, and being driven in low power consumption through the heat dissipation plate.

According to one or more aspects of the present disclosure, a heat dissipation plate may be provided that includes a guide holder for placing a circuit film on one surface of the heat dissipation plate and is capable of placing the circuit film and a source PCB connected to the circuit film at an intended location, and a display device including the heat dissipation plate may be provided.

According to one or more aspects of the present disclosure, a heat dissipation plate may be provided that includes a guide holder for enabling a driver IC to be spaced apart from the heat dissipation plate, and is capable of preventing the driver IC from interfering with the heat dissipation plate, and a display device including the heat dissipation plate may be provided.

Effects or advantages from aspects, examples, and embodiments described herein are not limited thereto, and additional effects or advantages will become apparent to those skilled in the art from the following description.

### BRIEF DESCRIPTION OF THE SEVERAL VIEWS OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 is a perspective view of an example heat dissipation plate according to aspects of the present disclosure;

FIG. 2 illustrates an example configuration where a display panel is placed on the heat dissipation plate of FIG. 1 according to aspects of the present disclosure;

FIG. 3 illustrates an example configuration where the display panel in FIG. 2 is bent according to aspects of the present disclosure;

FIG. 4 is an example cross-sectional view taken along line A-A′ of FIG. 3.

FIG. 5 is a front perspective view of an example display device according to aspects of the present disclosure; and

FIG. 6 is a rear perspective view of the display device in FIG. 5.

### DETAILED DESCRIPTION

Hereinafter, the present preferred embodiments of the disclosure will be described in detail with reference to the accompanying drawings. In denoting elements of the drawings by reference numerals, the same elements will be referenced by the same reference numerals although the elements are illustrated in different drawings. In the following description of the disclosure, detailed description of known functions and configurations incorporated herein may be omitted when it may make the subject matter of the disclosure rather unclear. The terms such as “including”, “having”, “containing”, “comprising of”, and “consist of” used herein are generally intended to allow other components to be added unless the terms are used with the term “only”. An element described in the singular form is intended to include a plurality of elements, and vice versa, unless the context clearly indicates otherwise.

Further, the terms “first”, “second”, “A”, “B”, “(a)”, “(b)”, or the like may be used to describe elements included in embodiments of the present disclosure. These terms are used only to distinguish one element from another; thus, related elements should not be interpreted to be limited by these terms as they are not used to define a particular order or precedence.

Further, the expression of a first element, a second elements “and/or” a third element should be understood as one of the first, second and third elements or as any or all combinations of the first, second and third elements. By way of example, A, B and/or C can refer to only A, only B, or only C; any or some combination of A, B, and C; or all of A, B, and C.

For the expression that an element or layer is “connected,” “coupled,” or “adhered” to another element or layer, the element or layer can not only be directly connected, coupled, or adhered to another element or layer, but also be indirectly connected, coupled, or adhered to another element or layer with one or more intervening elements or layers “disposed” or “interposed” between the elements or layers, unless otherwise specified. Further, the another element may be included in one or more of the two or more elements connected, combined, coupled, or contacted (to) one another.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers “disposed” or “interposed” between the elements or layers, unless otherwise specified.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used. In construing an element, the element is to be construed as including an error or tolerance range even where no explicit description of such an error or tolerance range is provided. Further, the term “may” fully encompasses all the meanings of the term “can.” The term “at least one” should be understood as including any or all combinations of one or more of the associated listed items. For example, the meaning of “at least one of a first element, a second element, and a third element” encompasses the combination of all three listed elements, combinations of any two of the three elements, as well as each individual element, the first element, the second element, and the third element. The expression of a first element, a second elements “and/or” a third element should be understood as one of the first, second and third elements or as any or all combinations of the first, second and third elements. By way of example, A, B and/or C can refer to only A, only B, or only C; any or some combination of A, B, and C; or all of A, B, and C. Hereinafter, various example embodiments of the present disclosure will be described in detail with reference to the accompanying drawings. In addition, for convenience of description, a scale in which each of elements is illustrated in the accompanying drawings may differ from an actual scale. Thus, the illustrated elements are not limited to the specific scale in which they are illustrated in the drawings.

Hereinafter, with reference to the accompanying drawings, various embodiments of the present disclosure will be described in detail.

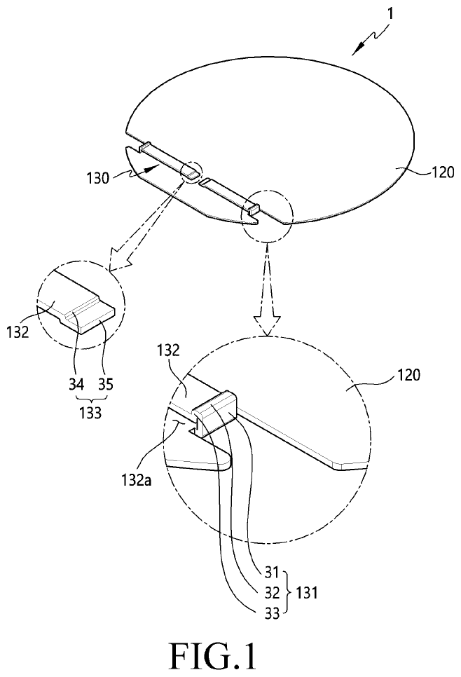

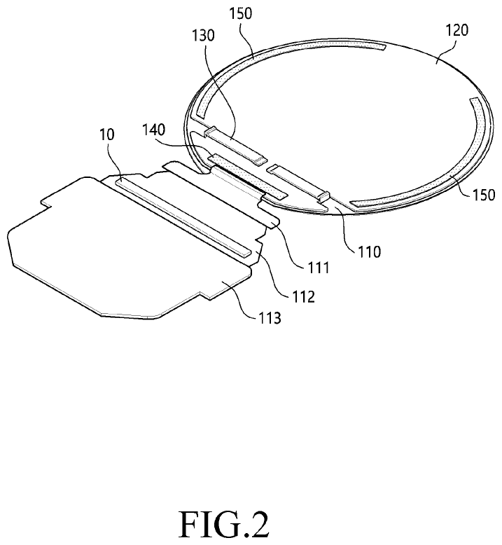

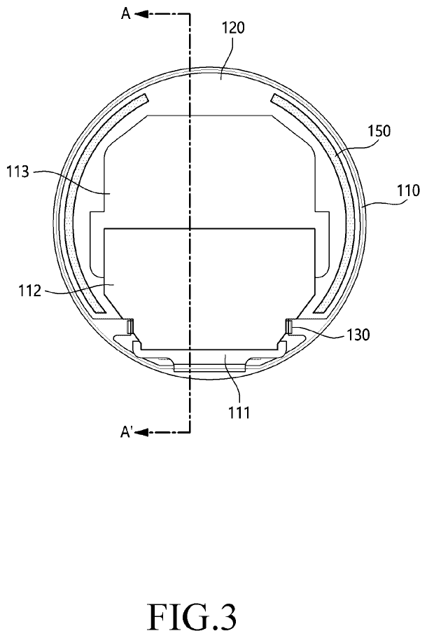

FIG. 1 is a perspective view of an example heat dissipation plate according to aspects of the present disclosure. FIG. 2 illustrates an example configuration where a display panel is placed on the heat dissipation plate of FIG. 1 according to aspects of the present disclosure. FIG. 3 illustrates an example configuration where the display panel in FIG. 2 is bent according to aspects of the present disclosure.

Referring to FIGS. 1 to 3, in one or more example embodiments, a heat dissipation plate 1 may be used for dissipating heat generated from a display panel 110 to the outside and include a base substrate 120 and a guide holder 130.

One surface (which may be referred to as a first surface) of the base substrate 120 may be placed on the rear surface of the display panel 110. For example, the rear surface of the display panel 110 may be placed on the front surface (e.g., the first surface) of the base substrate 120. Further, a pad portion 111 bent from the display panel 110, and a circuit film 112 and a source PCB 113 electrically connected to the pad portion 111 may be placed on the rear surface (e.g., a second surface) of the base substrate 120.

The base substrate 120 may include any material having high thermal conductivity, for example, any one selected from aluminum (Al), copper (Cu), zinc (Zn), silver (Ag), gold (Au), iron (Fe), and an alloy thereof. For example, the base substrate 120 may include aluminum (Al) having the characteristics of high thermal conductivity, low weight, and low cost, but aspects of the present disclosure are not limited thereto.

The base substrate 120 may be formed in the same shape as an outer shape of the display panel 110. For example, when the display panel 110 has a circular shape, the base substrate 120 may be formed in a circular plate shape, or when the display panel 110 has a square shape, the base substrate 120 may be formed in a square plate shape. As the base substrate 120 has the same shape as the outer shape of the display panel 110, an area of the base substrate 120 contacting the display panel 110 can be maximized and heat dissipation efficiency of the base substrate 120 can be improved.

The guide holder 130 may serve to place the circuit film 112 of the display panel 110 and may be disposed on the other surface (e.g., which may be referred to as the second surface) of the base substrate 120. For example, a pad portion 111, a circuit film 112, and a source PCB 113 may be electrically connected to a portion (e.g., a side or edge) of the display panel 110. In this configuration, as shown in FIG. 2, when the pad portion 111, the circuit film 112, and the source PCB 113 are disposed parallel to the display panel 110, a large space may be needed for placing these components. To address this issue, as shown in FIG. 3, the pad portion 111 may be bent, and thereby, the pad portion 111, the circuit film 112, and the source PCB 113 may be located on the rear surface (e.g., the second surface) of the base substrate 120.

For example, the pad portion 111 connected to the display panel 110 may be attached to the base substrate 120 through a first adhesive 140 placed on the second surface of the base substrate 120. For example, the first adhesive 140 may be disposed on a lower portion, or lower surface, of the guide holder 130 and be a double-sided tape.

The circuit film 112 connected to a portion of the pad portion 111 may be placed on the guide holder 130. For example, the circuit film 112 may be a chip on film (COF) using a flexible film substrate. The source PCB 113 connected to a portion of the circuit film 112 may be placed in a portion of the base substrate 120 located in an upward area from the guide holder 130.

As the pad portion 111 is attached to the base substrate 120 by the first adhesive 140, it is important to place the circuit film 112 connected to the pad portion 111 at an intended location. When the circuit film 112 is disposed at an unintended location, there may occur a situation where the pad portion 111 connected to the circuit film 112 is needed to be separated from the first adhesive 140, which may cause damage to the pad portion 111.

To address this issue, in one or more aspects, the heat dissipation plate 1 may include the guide holder 130 to guide a location at which the circuit film 112 is placed. For example, the guide holder 130 may be in the form of a pair of first and second guide holders 130. In this example, the first and second guide holders 130 of the guide holder 130 may be extending from first and second portions of the base substrate 120, respectively, and be bent so that the first and second guide holders 130 can be disposed in parallel to each other in the horizontal direction on the second surface of the base substrate 120.

Each of the first and second guide holders 130 may include a protrusion part 131, a support part 132, and a movement prevention part 133.

The protrusion part 131 may be disposed in a bending area where the base substrate 120 and the guide holder 130 contact each other. For example, a distance between the protrusion parts 131 disposed in the first and second portions of the base substrate 120, respectively, may correspond to a width of the circuit film 112. According to this configuration, when the circuit film 112 is placed on the guide holder 130, both ends of the circuit film 112 may be located within the protrusion parts 131. For example, the circuit film 112 can be placed at an intended location through the protrusion parts 131.

The protrusion part 131 may include a first body bent from any one of the first and second portions (e.g., both ends) of the base substrate 120 in the vertical direction, a second body bent inwardly from an end of the first body, and a third body bent from an end of the second body toward the base substrate 120. For example, the third body may have a shorter length than the first body.

The support part 132 may serve to place the circuit film 112. The support part 132 may extend from the protrusion part 131 and be disposed to face the base substrate 120. For example, the support part 132 may extend from the end of the third body, and be disposed in the horizontal direction on the base substrate 120. In this configuration, since the third body has a length shorter than the first body, there may be present a gap 132a formed between the support part 132 extending from the end of the third body and the base substrate 120. This gap 132a may serve to prevent interference with a driver IC 10 disposed on the circuit film 112. Discussions for the gap 132a will be described in detail later.

The movement prevention part 133 may extend from an end of the support part 132 and be supported by the base substrate 120. For example, the movement prevention part 133 may include a fourth body 34 bent from an end of the support part 132 toward the base substrate 120, and a fifth body 35 bent outwardly from the fourth body 34 and supported by the base substrate 120. For example, when a gap 132a is formed between the base substrate 120 and the support part 132 due to the protrusion part 131, to prevent the support part 132 from moving from the base substrate 120, the movement prevention part 133 can be provided at the end of the support part 132 on the base substrate 120. According to this configuration, as the end of the support part 132 is disposed on the base substrate 120 through the movement prevention part 133, movement of the support part 132 can be prevented. The movement prevention part 133 may be disposed on the base substrate 120 without a separate fixing element, or may be fixed on the base substrate 120 through a fixing element such as a double-sided tape.

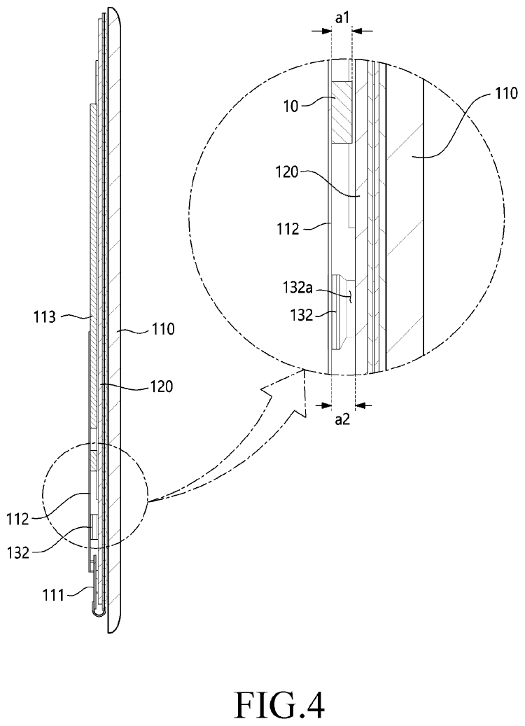

FIG. 4 is an example cross-sectional view taken along line A-A′ of FIG. 3.

Referring to FIG. 4, the circuit film 112 of the display panel 110 may include a driver IC 10 disposed on one surface of the circuit film 112 and facing the second surface of the base substrate 120. In a situation where there occurs an interference between the driver IC 10 and the base substrate 120, a crack may occur in the driver IC 10. Therefore, it is important to place the driver IC 10 to be spaced apart from the base substrate 120.

In one or more aspects, to prevent an interference between the driver IC 10 and the base substrate 120, the guide holder 130 may be placed to be spaced apart from the base substrate 120 by a distance a2 greater than a thickness a1 of the driver IC 10. For example, an outer surface of the support part 132 supporting the circuit film 112 may be placed to be spaced apart from the base substrate 120 by the distance a2 greater than the thickness a1 of the driver IC 10. For example, the sum of a distance of the gap 132a between the base substrate 120 and the support part 132 and the thickness of the support part 132 may be greater than the thickness of the driver IC 10.

Accordingly, when the circuit film 112 is placed on the support part 132, the driver IC 10 of the circuit film 112 can be spaced apart from the base substrate 120, and thereby, interference between the driver IC 10 and the support part 132 can be prevented. According to the foregoing configurations, damage to the driver IC 10 due to interference between the driver IC 10 and the base substrate 120 can be prevented.

As discussed above, as the heat dissipation plate 1 includes the guide holder 130 for placing the circuit film 112 of the display panel 110 on the second surface of the base substrate 120, the circuit film 112 and the source PCB 113 connected to the circuit film 112 can be placed at intended locations.

Further, by forming the gap 132a between the guide holder 130 and the base substrate 120, the driver IC 10 disposed on the circuit film 112 placed on the guide holder 130 can be prevented from interfering with the base substrate 120.

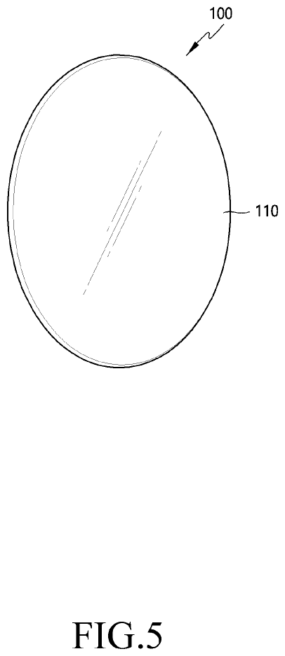

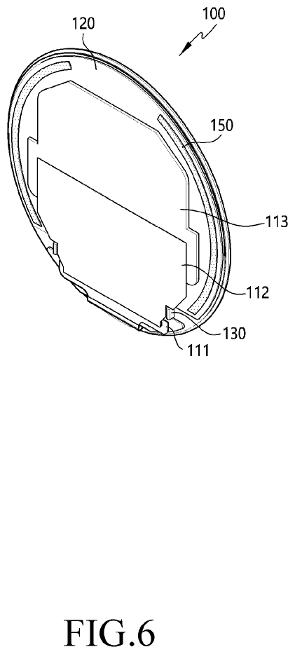

FIG. 5 is a front perspective view of the display device 100 according to aspects of the present disclosure. FIG. 6 is a rear perspective view of the display device 100 in FIG. 5. Discussions that follow for the configurations of FIGS. 5 and 6 are provided by focusing on configurations different from the configurations of FIGS. 1 to 4, for simplicity.

Referring to FIGS. 1 to 6, in one or more example embodiments, the display device 100 may include the display panel 110, and the heat dissipation plate 1 including the base substrate 120 and the guide holder 130.

In one or more aspects, the display device 100 may be installed in a cockpit of a vehicle to provide images to a driver and passengers. However, aspects of the present disclosure are not limited thereto. For example, the display device 100 may be applied to various devices such as mobile communication terminals, laptops, and the like.

The display panel 110 may include a display area where an image can be displayed and a non-display area where an image is not displayed. The non-display area may be an area outside of the display area, and may also be referred to as an non-active area, or a bezel area.

The display panel 110 may include the pad portion 111, the circuit film 112, and the source PCB 113. For example, a plurality of pad portions 111 provided in a portion (e.g., a side or edge) of the display panel 110 and connected to the display area may be connected to the source PCB 113 through the circuit film 112.

The circuit film 112 may be electrically connected to the pad portion 111 and can supply signals to a plurality of subpixels and circuits arranged in the display area. For example, the circuit film 112 may be a chip on film (COF) using a flexible film substrate. The number of circuit films 112 is not limited to this example, and may be changed in various configuration depending on design requirements.

The circuit film 112 may include at least one driver IC 10 for processing data for displaying an image. For example, the driver IC 10 may be disposed on one surface of the circuit film 112, and be disposed such that the driver IC 10 faces the second surface of the base substrate 120 when the circuit film 112 is bent.

The source PCB 113 can supply a signal to the driver IC 10, and may be disposed in a portion of the circuit film 112 so that the source PCB 113 can be electrically connected to the circuit film 112. For example, the source PCB 113 can supply various signals such as a driving signal, a data signal, and/or the like to the driver IC 10. It should be noted that although one source PCB 113 is illustrated in FIG. 6, but aspects of the present disclosure are not limited thereto. For example, the number of the source PCBs 113 may be changed variously depending on design requirements.

The heat dissipation plate 1 may include the base substrate 120 and the guide holder 130.

A first surface of the base substrate 120 may be placed on the rear surface of the display panel 110. For example, the rear surface of the display panel 110 may be placed on the front surface (e.g., the first surface) of the base substrate 120. Further, a pad portion 111 bent from the display panel 110, and a circuit film 112 and a source PCB 113 electrically connected to the pad portion 111 may be placed on the rear surface (e.g., a second surface) of the base substrate 120.

The guide holder 130 may serve to place the circuit film 112 bent from the display panel 110 and be disposed on the second surface of the base substrate 120. For example, the pad portion 111 connected to a portion of the display panel 110 may be bent and placed on the rear surface of the base substrate 120, and the circuit film 112 connected to the pad portion 111 may be placed on the guide holder 130, so that a disposed location of the circuit film 112 can be guided by the guide holder 130. Therefore, the pad portion 111 and the source PCB 113 respectively connected to a portion and another portion of the circuit film 112 can also be placed at intended locations.

In one or more aspects, the pad portion 111 may be attached to the base substrate 120 by the first adhesive 140, in this implementation, since a disposed location of the pad portion 111 is guided by the guide holder 130, the pad portion 111 can be placed at an intended location. Therefore, since there may not occur a situation where the pad portion 111 is needed to be separated from the first adhesive 140 due to an undesirable attachment, damage to the pad portion 111 can be prevented.

The first and second guide holders 130 of the guide holder 130 may extend from first and second portions of the base substrate 120, respectively, and be bent so that the first and second guide holders 130 can be disposed in parallel to each other in the horizontal direction on the second surface of the base substrate 120.

Each of the first and second guide holders 130 may include the protrusion part 131, the support part 132, and the movement prevention part 133.

The protrusion part 131 may be disposed in a bending area where the base substrate 120 and the guide holder 130 contact each other. For example, a distance between the protrusion parts 131 disposed in the first and second portions of the base substrate 120, respectively, may correspond to a width of the circuit film 112. According to this configuration, when the circuit film 112 is placed on the guide holder 130, both ends of the circuit film 112 may be located in the protrusion parts 131. For example, the circuit film 112 can be placed at an intended location through the protrusion parts 131.

The protrusion part 131 may include a first body 31 bent from any one of the first and second portions (e.g., both ends) of the base substrate 120 in the vertical direction, a second body 32 bent inwardly from an end of the first body, and a third body 33 bent from an end of the second body portion toward the base substrate 120. For example, the third body 33 may have a shorter length than the first body 31.

The support part 132 may serve to place the circuit film 112. The support part 132 may extend from the protrusion part 131, and be disposed to face the base substrate 120. In this configuration, since the third body 33 has a length shorter than the first body 31, there may be present a gap 132a formed between the support part 132 extending from the end of the third body 33 and the base substrate 120.

For example, the sum of a distance of the gap 132a between the base substrate 120 and the support part 132 and the thickness of the support part 132 may be greater than the thickness of the driver IC 10 and less than a length of the first body 31. Accordingly, an interference between the driver IC 10 and the base substrate 120 can be prevented, and the display device 100 can be provided with a thinner and lighter package by minimizing the size of the gap 132a.

The movement prevention part 133 may extend from an end of the support part 132 and be supported by the base substrate 120. For example, the movement prevention part 133 may include a fourth body 34 bent from an end of the support part 132 toward the base substrate 120, and a fifth body 35 bent outwardly from the fourth body 34 and placed on the base substrate 120. The movement prevention part 133 may be disposed on the base substrate 120 without a separate fixing element, or may be fixed on the base substrate 120 through a fixing element such as a double-sided tape.

In one or more aspects, the display device 100 may be applied in a vehicle. For example, the display device 100 may be attached to a vehicle through a second adhesive 150 disposed along an edge of the second surface of the base substrate 120. In this example, the second adhesive 150 may be in the form of a pair of first-second and second-second adhesives 150. For example, the first-second and second-second adhesives 150 may be disposed along left and right edges of the base substrate 120, respectively, and be disposed in such a manner that the first-second and second-second adhesives 150 do not interfere with the circuit film 112 and the source PCB 113. For example, the second adhesive 150 may be a double-sided adhesive tape, but aspects of the present disclosure are not limited thereto.

According to the examples, aspects, and embodiments described herein, the display device may be described as follows.

According to the one or more example embodiments described herein, a heat dissipation plate for a display device can be provided that includes a base substrate allowing a rear surface of a display panel including a pad portion, a circuit film, and a source PCB that are disposed on a side of the display panel to be disposed on one surface of the base substrate, and a guide holder disposed on the other surface of the base substrate and allowing a circuit film bent from the display panel to be placed.

In one or more aspects, the guide holder may be in the form of a pair of first and second guide holders, and the first and second guide holders may respectively extend from first and second portions of the base substrate, be bent, and be disposed in parallel to each other in a horizontal direction on the second surface of the base substrate.

In one or more aspects, the guide holder comprises first and second guide holders, and each of the first and second guide holders may include a protrusion part disposed in a bending area where the guide holder and the base substrate contact each other, a support part extending from the protrusion part and allowing the circuit film to be placed, and a movement prevention part extending from the support part and supported by the base substrate.

In one or more aspects, a distance between the protrusion part of the first guide holder and the protrusion part of the second guide holder respectively disposed in first and second portions of the base substrate may correspond to a width of the circuit film.

In one or more aspects, the protrusion part may include a first body bent in a vertical direction from any one of first and second portions of the base substrate, a second body bent inwardly from the first body, and a third body bent from the second body toward the base substrate.

In one or more aspects, the third body may have a length less than that of the first body, and the support part may extend from the third body and disposed such that a gap between the support part and the base substrate can be formed.

In one or more aspects, the circuit film comprises a driver IC facing the second surface of the base substrate, and wherein a sum of a distance of the gap formed between the base substrate and the support part and a thickness of the support part is greater than a thickness of the driver IC and less than a length of the first body.

In one or more aspects, the movement prevention part may include a fourth body bent from the support part toward the base substrate, and a fifth body bent outwardly from the fourth body and supported by the base substrate.

In one or more aspects, the guide holder may be disposed to be spaced apart from the base substrate by a distance greater than a thickness of a driver IC disposed on the circuit film.

In one or more aspects, the heat dissipation plate may further include a first adhesive disposed on the second surface of the base substrate and attaching the pad portion to the base substrate.

In one or more aspects, the heat dissipation plate may further include a second adhesive disposed along an edge of the second surface of the base substrate such that the second adhesive does not interfere with the circuit film and the source PCB.

According to the one or more example embodiments described herein, a heat dissipation plate for a display device can be provided that includes a display panel including a pad portion, a circuit film, and a source PCB, which are disposed on a side of the display panel, and a heat dissipation plate including a base substrate allowing a rear surface of the display panel to be disposed on a first surface of the base substrate, and a guide holder disposed on a second surface of the base substrate and allowing the circuit film bent from the display panel to be placed.

In one or more aspects, the guide holder may be in the form of a pair of first and second guide holders, and the first and second guide holders may respectively extend from first and second portions of the base substrate, be bent, and be disposed in parallel to each other in a horizontal direction on the second surface of the base substrate.

In one or more aspects, the guide holder comprises first and second guide holders, and each of the first and second guide holders may include a protrusion part disposed in a bending area where the guide holder and the base substrate contact each other, a support part extending from the protrusion part and allowing the circuit film to be placed, and a movement prevention part extending from the support part and supported by the base substrate.

In one or more aspects, a distance between the protrusion part of the first guide holder and the protrusion part of the second guide holder respectively disposed in first and second portions of the base substrate may correspond to a width of the circuit film.

In one or more aspects, the guide holder is configured to guide the pad portion and the circuit film to an intended location.

In one or more aspects, the protrusion part may include a first body bent in a vertical direction from any one of first and second portions of the base substrate, a second body bent inwardly from the first body, and a third body bent from the second body toward the base substrate.

In one or more aspects, the third body may have a length less than that of the first body, and the support part may extend from the third body and disposed such that a gap between the support part and the base substrate can be formed.

In one or more aspects, the circuit film may include a driver IC facing the second surface of the base substrate. In one or more aspects, a sum of a distance of the gap formed between the base substrate and the support part and a thickness of the support part may be greater than a thickness of the driver IC and less than a length of the first body.

In one or more aspects, the movement prevention part may include a fourth body bent from the support part toward the base substrate, and a fifth body bent outwardly from the fourth body and supported by the base substrate.

In one or more aspects, the circuit film may include a driver IC facing the second surface of the base substrate, and the guide holder may be spaced apart from the base substrate by a distance greater than a thickness of the driver IC.

In one or more aspects, the display device may further include a first adhesive disposed on the second surface of the base substrate and attaching the pad portion to the base substrate, and a second adhesive disposed along an edge of the second surface of the base substrate such that the second adhesive does not interfere with the circuit film and the source PCB.

The embodiments of the present disclosure described above have been described for illustrative purposes; those skilled in the art will appreciate that various modifications, additions and substitutions are possible, without departing from the scope and spirit of the disclosure. Although the exemplary embodiments have been described for illustrative purposes, a person skilled in the art will appreciate that various modifications and applications are possible without departing from the essential characteristics of the present disclosure. For example, the specific components of the exemplary embodiments may be variously modified.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A heat dissipation plate comprising:
a base substrate;
a display panel having a rear surface and a pad portion, a circuit film, and a source PCB on the rear surface, wherein a side of the display panel is disposed on a first surface of the base substrate; and
a guide holder disposed on a second surface of the base substrate, wherein the circuit film is bent from the display panel and the guide holder secures the bent circuit film.

2. The heat dissipation plate of claim 1, wherein the guide holder includes a pair of first and second guide holders, and the first and second guide holders respectively extend from first and second portions of the base substrate, are each bent, and are disposed in parallel to each other in a horizontal direction on the second surface of the base substrate.

3. The heat dissipation plate of claim 1, wherein the guide holder comprises first and second guide holders, and each of the first and second guide holders comprises:
a protrusion disposed in a bending area where the guide holder and the base substrate contact each other;
a support extending from the protrusion to assist in securing the circuit film; and
a plate extending from an end of the support, wherein the plate is supported by the base substrate.

4. The heat dissipation plate of claim 3, wherein a distance between the protrusion of the first guide holder and the protrusion of the second guide holder respectively disposed in first and second portions of the base substrate corresponds to a width of the circuit film.

5. The heat dissipation plate of claim 3, wherein the protrusion comprises a first body bent in a vertical direction from any one of first and second portions of the base substrate, a second body bent inwardly from an end of the first body, and a third body bent from an end of the second body toward the base substrate.

6. The heat dissipation plate of claim 5, wherein the third body has a length less than a length of the first body, and
wherein the support extends from an end of the third body to define a gap between the support part and the base substrate.

7. The heat dissipation plate of claim 6, wherein the circuit film comprises a driver IC facing the second surface of the base substrate, and
wherein a sum of a distance of the gap between the base substrate and the support and a thickness of the support is greater than a thickness of the driver IC and less than the length of the first body.

8. The heat dissipation plate of claim 3, wherein the plate comprises a fourth body bent from the end of the support toward the base substrate, and a fifth body bent outwardly from the fourth body and supported by the base substrate.

9. The heat dissipation plate of claim 1, wherein the guide holder is spaced from the base substrate by a distance greater than a thickness of a driver IC disposed on the circuit film.

10. The heat dissipation plate of claim 1, further comprising a first adhesive disposed on the second surface of the base substrate and coupling the pad portion to the base substrate.

11. The heat dissipation plate of claim 1, further comprising a second adhesive disposed along an edge of the second surface of the base substrate such that the second adhesive does not interfere with the circuit film and the source PCB.

12. A display device comprising:
a display panel comprising a pad portion, a circuit film, and a source PCB disposed on a side of the display panel; and
a heat dissipation plate comprising a base substrate, wherein a rear surface of the display panel is disposed on a first surface of the base substrate, and the heat dissipation plate further includes a guide holder disposed on a second surface of the base substrate to secure the circuit film bent from the display panel.

13. The display device of claim 12, wherein the guide holder includes a pair of first and second guide holders, and the first and second guide holders respectively extend from first and second portions of the base substrate, are bent, and are disposed in parallel to each other in a horizontal direction on the second surface of the base substrate.

14. The display device of claim 12, wherein the guide holder comprises first and second guide holders, and each of the first and second guide holders comprises:
a protrusion disposed in a bending area where the guide holder and the base substrate contact each other;
a support extending from the protrusion to assist in securing the circuit film; and
a movement prevention part extending from an end of the support and supported by the base substrate.

15. The display device of claim 14, wherein a distance between the protrusion of the first guide holder and the protrusion of the second guide holder respectively disposed in first and second portions of the base substrate corresponds to a width of the circuit film.

16. The display device of claim 15, wherein the guide holder is configured to guide the pad portion and the circuit film to an intended location.

17. The display device of claim 14, wherein the protrusion comprises a first body bent in a vertical direction from any one of first and second portions of the base substrate, a second body bent inwardly from an end of the first body, and a third body bent from an end of the second body toward the base substrate.

18. The display device of claim 17, wherein the third body has a length less than a length of the first body, and
wherein the support extends from an end of the third body, and is disposed such that a gap between the support part and the base substrate is formed.

19. The display device of claim 18, wherein the circuit film comprises a driver IC facing the second surface of the base substrate, and
wherein a sum of a distance of the gap between the base substrate and the support part and a thickness of the support is greater than a thickness of the driver IC and less than the length of the first body.

20. The display device of claim 14, wherein the movement prevention part comprises a fourth body bent from the support toward the base substrate, and a fifth body bent outwardly from the fourth body and supported by the base substrate.

21. The display device of claim 12, wherein the circuit film comprises a driver IC facing the second surface of the base substrate, and the guide holder is spaced apart from the base substrate by a distance greater than a thickness of the driver IC.

22. The display device of claim 12, further comprising:
a first adhesive disposed on the second surface of the base substrate and attaching the pad portion to the base substrate; and
a second adhesive disposed along an edge of the second surface of the base substrate such that the second adhesive does not interfere with the circuit film and the source PCB.
